(19) United States
(12) Patent Application Publication
(10) Pub. No.: US 2025/0386643 A1
(43) Pub. Date: Dec. 18, 2025

(54) DISPLAY DEVICE, ELECTRONIC APPARATUS AND METHOD OF MANUFACTURING DISPLAY DEVICE

(71) Applicant: Samsung Display Co., LTD., Yongin-si (KR)

(72) Inventors: In Tae SON, Yongin-si (KR); Won Seok KIM, Yongin-si (KR); Jue Youn PARK, Yongin-si (KR); Kang Woo LEE, Yongin-si (KR); Da Song LEE, Yongin-si (KR); Hyun Jung LEE, Yongin-si (KR); Jin Yeong HEO, Yongin-si (KR)

(21) Appl. No.: 19/079,134

(22) Filed: Mar. 13, 2025

(30) Foreign Application Priority Data
Jun. 17, 2024 (KR) 10-2024-0078268
Aug. 30, 2024 (KR) 10-2024-0117330

(51) Int. Cl. H10H 29/85; H10H 29/01

(52) U.S. Cl. CPC H10H 29/8506; H10H 29/012

(57) ABSTRACT

In a method of manufacturing a display device, the method may include: selecting a pre-adhesive layer by measuring a free volume of the pre-adhesive layer; and forming an adhesive layer and a cover window on a display panel. In the selecting of the pre-adhesive layer, the pre-adhesive layer selected may form the adhesive layer.

### CROSS-REFERENCE TO RELATED APPLICATION

The present application claims priority to and the benefit of Korean Patent Application No. 10-2024-0078268, filed on Jun. 17, 2024, and Korean Patent Application No. 10-2024-0117330, filed on Aug. 30, 2024, in the Korean Intellectual Property Office, the entire content of which is hereby incorporated by reference.

### BACKGROUND

### 1. Field

Embodiments of the present disclosure generally relate to a display device and a method of manufacturing a display device. An electronic apparatus may include the display device.

### 2. Description of Related Art

With the development of information technologies, the importance of a display device which is a connection medium between a user and information has increased. Accordingly, research and development of display devices have been continuously conducted.

In a display device, a cover window that protects lower structures is provided on a display panel, and an Optically Clear Adhesive (OCA) is used to bond between the display panel and the cover window. The OCA should basically have excellent moisture resistance or protection (e.g., be moisture proof), excellent heat resistance, and excellent adhesive strength together with optical characteristics.

### SUMMARY

Embodiments of the present disclosure provide a display device and a method of manufacturing a display device, in which reliability against infiltrated bubbles can be improved.

In accordance with an aspect of embodiments of the present disclosure,

there is provided a method of manufacturing a display device, the method including: selecting a pre-adhesive layer by measuring a free volume of the pre-adhesive layer; and forming an adhesive layer and a cover window on a display panel, wherein, in the selecting of the pre-adhesive layer, the pre-adhesive layer selected forms the adhesive layer.

The free volume of the pre-adhesive layer selected may be less than 0.035 times of a volume (e.g., a total volume) of the pre-adhesive layer.

The selecting of the pre-adhesive layer may include not selecting the pre-adhesive layer when the free volume of the pre-adhesive layer is 0.035 times or more of the volume (e.g., the total volume) of the pre-adhesive layer.

In the selecting of the pre-adhesive layer, the free volume may be measured using a positive electron extinction method.

The free volume may be derived by substituting a value R calculated from Expression 1 in

$$\frac{4 π {R}^{3}}{3} :$$

$$τ 3 = 0.5 \times {[ 1 - \frac{R}{R + Δ R} + \frac{1}{2 π} sin ( \frac{2 π R}{R + Δ R} ) ]}^{- 1} \qquad Expression 1$$

in Expression 1, τ₃ is a lifetime of orthopositronium (o-PS), which is measured using the positive electron extinction method, R is an average radius of the free volume when the pre-adhesive layer is assumed to be a sphere, and ΔR is 0.1656 nm.

The forming of the adhesive layer and the cover window on the display panel may include: laminating the pre-adhesive layer selected on the display panel; forming the cover window on the pre-adhesive layer; and performing an autoclave process.

The laminating may include laminating the pre-adhesive layer, using a roller, or laminating the pre-adhesive layer by inputting the pre-adhesive layer to a vacuum chamber.

In the selecting of the pre-adhesive layer, the free volume may be derived by substituting the following a value R calculated Expression 1 in

$$\frac{4 π {R}^{s}}{\text{?}} ,$$

$$\text{?} \text{indicates text missing or illegible when filed}$$

and in the selecting of the pre-adhesive layer, the selected pre-adhesive layer may satisfy Expression 2:

$$τ 3 = 0.5 \times {[ 1 - \frac{R}{R + Δ R} + \frac{1}{2 π} sin ( \frac{2 π R}{R + Δ R} ) ]}^{- 1} , \qquad Expression 1$$

in Expression 1, τ₃ is a lifetime of orthopositronium (o-PS), which is measured using a positive electron extinction method, R is an average radius of the free volume when the pre-adhesive layer is assumed to be a sphere, and ΔR is 0.1656 nm, and

$$Free Volume of Pre - adhesive \text{} Layer / Volume of Pre - adhesive Layer < 0.035 . \qquad Expression 2$$

The adhesive layer may be between the display panel and the cover window.

In accordance with another aspect of embodiments of the present disclosure, there is provided a display device including: a display panel; an adhesive layer on the display panel; and a cover window on the adhesive layer, wherein a free volume of the adhesive layer is less than 0.035 times of a volume of the adhesive layer.

$$\frac{4 π {R}^{s}}{\text{?}}$$

$$\text{?} \text{indicates text missing or illegible when filed}$$

The free volume may be derived by substituting the following value R in through Expression 1:

$$τ 3 = 0.5 \times {[ 1 - \frac{R}{R + Δ R} + \frac{1}{2 π} sin ( \frac{2 π R}{R + Δ R} ) ]}^{- 1} , \qquad Expression 1$$

in Expression 1, τ₃ is a lifetime of orthopositronium (o-PS), which is measured using a positive electron extinction method, R is an average radius of the free volume when the adhesive layer is assumed to be a sphere, and ΔR is 0.1656 nm. A bottom surface of the adhesive layer may be in contact with the display

panel, and a top surface of the adhesive layer may be in contact with the cover window.

According to one or more embodiments, an electronic apparatus includes a display device, and a housing accommodating the display apparatus, wherein the display device includes a display panel; an adhesive layer on the display panel; and a cover window on the adhesive layer, wherein a free volume of the adhesive layer is less than 0.035 times of a volume of the adhesive layer.

### BRIEF DESCRIPTION OF THE DRAWINGS

Example embodiments of the present disclosure will now be described more

fully hereinafter with reference to the accompanying drawings; however, the subject matter of the present disclosure may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIGS. 1-2 are cross-sectional views schematically illustrating a display device in accordance with an embodiment of the present disclosure.

FIGS. 3-5 are plan views schematically illustrating an electronic device including a display device in accordance with an embodiment of the present disclosure.

FIG. 6 is a plan view schematically illustrating a display panel in accordance with an embodiment of the present disclosure.

FIG. 7 is an equivalent circuit diagram of a pixel in accordance with an embodiment of the present disclosure.

FIG. 8 is a cross-sectional view schematically illustrating a stacked structure of a display panel in accordance with an embodiment of the present disclosure.

FIG. 9 is a schematic flowchart illustrating a manufacturing method of a display device in accordance with an embodiment of the present disclosure.

FIGS. 10-11 are schematic sectional views illustrating process steps of the method in accordance with an embodiment of the present disclosure.

FIG. 12 is a block diagram of an electronic device according to an embodiment.

FIG. 13 shows schematic views of various embodiments of an electronic device.

### DETAILED DESCRIPTION

Embodiments of the present disclosure may apply various suitable changes and different shapes, and therefore, only examples are illustrated in more detail. However, the examples do not limit the present disclosure to certain shapes but instead the present disclosure encompasses all suitable changes and equivalent materials and replacements. The accompanying drawings are illustrated in a fashion where the drawings may be expanded for better understanding.

It will be understood that, although the terms “first”, “second”, etc. may be used herein to describe various elements, these elements should not be limited by these terms. These terms are only used to distinguish one element from another element. Thus, a “first” element discussed below could also be termed a “second” element without departing from the spirit and scope of the present disclosure. As used herein, the singular forms are intended to include the plural forms as well, unless the context clearly indicates otherwise.

It will be further understood that the terms “includes” and/or “including”, when used in this specification, specify the presence of stated features, integers, steps, operations, elements, and/or components, but do not preclude the presence and/or addition of one or more other features, integers, steps, operations, elements, components, and/or groups thereof. An expression that an element such as a layer, region, substrate or plate is placed “on” or “above” another element indicates not only a case where the element is placed “directly on” or “just above” the other element but also a case where a further element is interposed between the element and the other element. An expression that an element such as a layer, region, substrate or plate is placed “beneath” or “below” another element indicates not only a case where the element is placed “directly beneath” or “just below” the other element but also a case where a further element is interposed between the element and the other element.

Embodiments of the present disclosure generally relate to a display device and a method of manufacturing a display device. Hereinafter, a display device and a method of manufacturing a display device in accordance with an embodiment of the present disclosure will be described with reference to the accompanying drawings. The kind of the display device in accordance with the present disclosure is

not limited to a specific example. For example, the display device may include an organic light emitting element, but the present disclosure is not limited thereto. In another embodiment, the display device in accordance with the embodiment of the present disclosure may be a display device including an inorganic light emitting element, or be a display device such as a display device including a quantum dot light emitting element. For example, a light emitting layer of a display element included in the display device may include an organic material, include an inorganic material, include a quantum dot, include an organic material and a quantum dot, and/or include an inorganic material and a quantum dot.

An electronic apparatus may include the display device. The electronic apparatus may include various suitable products including televisions, notebook computers, monitors, advertisement boards, and Internet of things (IOT) devices as well as portable electronic apparatuses including mobile phones, smartphones, tablet personal computers (PCs), mobile communication terminals, electronic organizers, electronic books, portable multimedia players (PMPs), navigations, and ultra mobile personal computers (UMPCs). In embodiments, the electronic apparatus may include wearable devices including smartwatches, watchphones, glasses-type displays, and head-mounted displays (HMDs). In embodiments, the electronic apparatus may include a display in instrument panels for automobiles, center fascias for automobiles, and/or center information displays (CIDs) on a dashboard, room mirror displays that replace side mirrors of automobiles, and/or displays of an entertainment system on the backside of front seats for backseat passengers in automobiles. The display device is an element that displays moving images and/or still images in various embodiments of the electronic apparatus and may be included in the electronic apparatus.

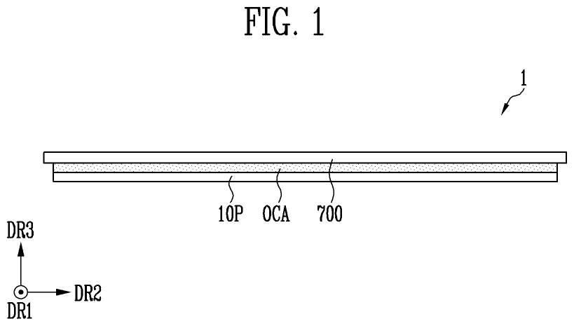

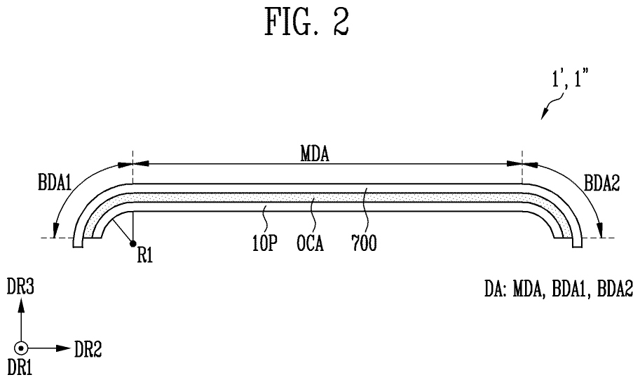

FIGS. 1-2 are cross-sectional views schematically illustrating a display device in accordance with an embodiment of the present disclosure.

Referring to FIGS. 1-2, a display device 1, 1′, and 1″ may include a display panel 10P and a cover window 700 that provides a top thereof. The display device 1 may have an entirely flat shape as shown in FIG. 1, and/or have a shape in which at least a partial area (e.g., a portion) is bent.

In the display device 1′ and 1″ shown in FIG. 2, a display area DA may include a main display area MDA, and a first bending display area BDA1 and a second bending display area BDA2, which correspond to a bending area. The first bending display area BDA1 and the second bending display area BDA2 may be bent while having a curvature radius R1. In FIG. 2, it is illustrated that the first bending display area BDA1 and the second bending display area BDA2 have the same curvature radius R1. However, in another embodiment, the first bending display area BDA1 and the second bending display area BDA2 may have curvature radii that are different from each other.

The display device 1′ and 1″ may include an adhesive layer OCA for allowing the display panel 10P and the cover window 700 to be bonded to each other therebetween. The adhesive layer OCA may be on the display panel 10P, to allow the cover window 700 to be attached to the display panel 10P. For example, a bottom surface of the adhesive layer OCA may be in contact with the display panel 10P, and a top surface of the adhesive layer OCA may be in contact with the cover window 700, so that the cover window 700 is bonded to the display panel 10P. In an embodiment, the adhesive layer OCA may be provided to have a same width and a same area as the display panel 10P.

In a process of allowing the display panel 10P and the cover window 700 to be attached to each other through the adhesive layer OCA, a pressurizing process (e.g., an autoclave process) may be performed on the adhesive layer OCA. The autoclave process may be a process of performing pressurization (e.g., at a pressure of 8 bar) so as to remove bubbles in the bending area under a high temperature (e.g., at a temperature of 60° C.). After the autoclave process under a high-temperature and high-pressure condition is completed, the display device 1, 1′, and 1″ may be restored to a condition of a normal temperature and a normal pressure (e.g., a temperature of 25° C. and a pressure of 1 bar).

In a comparative example, as ambient temperature and pressure become low after the autoclave process, a problem may occur, in that air infiltrated from the outside when an adhesive layer is pressurized remains in the adhesive layer. Hereinafter, this condition may be defined as ‘infiltrated bubbles.’ The infiltrated bubbles may correspond to bubbles occurring in the adhesive layer OCA after the adhesive layer OCA is attached in a manufacturing process as described above.

An edge area and/or the bending area of the display device is weaker due to the infiltrated bubbles. The infiltrated bubbles may be understood as infiltrated bubbles viewed in the edge area of the display device and/or an edge portion at which the bending area is formed, as bubbles confined in the adhesive layer do not escape from the adhesive layer but instead are condensed when a gas dissolved inside the adhesive layer under a pressurizing process condition of a high temperature and a high pressure (e.g., a temperature of 60° C. and a pressure of 8 bar) is restored to the normal temperature and the normal pressure (e.g., a temperature of 25° C. and a pressure of 1 bar).

Therefore, the reliability of the adhesive layer OCA provided in the edge area and/or the bending area to attach the cover window 700 to the display panel 10P may be significant (e.g., the reliability may be significantly reduced by the presence of the infiltrated bubbles).

Accordingly, the display device 1, 1′, and 1″ in accordance with embodiments of the present disclosure includes the adhesive layer OCA in which occurrence of the above-described infiltrated bubbles is minimized or reduced. Thus, the occurrence of the infiltrated bubbles is reduced even after the pressurizing process is completed, so that a defect rate in the edge area and/or the bending area of the display device 1, 1′, and 1″ can be reduced and the reliability of the display device 1, 1′, and 1″ can be improved.

A free volume of the adhesive layer OCA in accordance with embodiments of the present disclosure may be less than 3.5% of a volume (e.g., a total volume) of the adhesive layer OCA. For example, with respect to the volume (e.g., the total volume) of the adhesive layer OCA, the free volume of the adhesive layer OCA may be less than 0.035 times of the volume (e.g., the total volume) of the adhesive layer OCA. The free volume of the adhesive layer OCA may be 0% or more and less than 3.5% of the volume (e.g., the total volume) of the adhesive layer OCA.

The free volume of the adhesive layer OCA may be a volume obtained using a model suggested by Tao-Eldrup in a positive electron extinction method. The positive electron extinction method using the model suggested by Tao-Eldrup has been utilized as a method of obtaining a free volume of a polymer. In general, when positive electrons are incident onto the polymer, the positive electrons are combined with electrons, thereby generating positronium (Ps). The positive electron extinction method is a method of obtaining the free volume of the polymer by measuring a lifetime τ₃ of orthopositronium (o-Ps, a radium of 0.1 nm, and hereinafter, referred to as o-Ps) when o-PS occupying 3/4 of the positronium (Ps) enters into a cavity of the polymer. The lifetime τ₃ of o-Ps may be determined as a probability that positive electrons of o-Ps and electrons in a wall of the cavity will overlap with each other when the positive electrons of o-PS collide with the wall of the cavity existing in the polymer, and the lifetime τ₃ of o-Ps becomes longer as the cavity of the polymer becomes larger. A model for obtaining a speed of positive electron extinction, which is obtained by calculating overlapping of wave functions of an electron layer having a thickness of AR and o-PS when the cavity is considered as a spherical well type potential having an infinite height, and it is assumed that the electron layer exists in the wall of the cavity, is well-fitted with data when an experiment is actually performed. Therefore, a relation of Expression 1 is established between the lifetime τ₃ of o-Ps and a cavity diameter R.

$$τ 3 = 0.5 \times {[ 1 - \frac{R}{R + Δ R} + \frac{1}{2 π} sin ( \frac{2 π R}{R + Δ R} ) ]}^{- 1} \qquad Expression 1$$

In Expression 1, is the measured lifetime of orthopositronium (o-PS), R is an average radius of the free volume when the adhesive layer OCA is assumed as a sphere, and ΔR is an experientially determined constant, which is 0.1656 nm.

In embodiments, the lifetime τ₃ of orthopositronium (o-PS) is obtained by using the positive electron extinction method using the model suggested by Tao-Eldrup, so that the average radius R of the free volume when the adhesive layer OCA is assumed as a sphere is derived from Expression 1. In embodiments, because cavity volume (average free volume)=4/3×ττR³, the average free volume of the adhesive layer OCA may be calculated from the value of the obtained R.

In accordance with embodiments of the present disclosure, the free volume of the adhesive layer OCA may be less than 3.5% of the volume (e.g., the total volume) of the adhesive layer OCA, and thus occurrence of infiltrated bubbles when the display device 1, 1′, and 1″ is manufactured can be reduced.

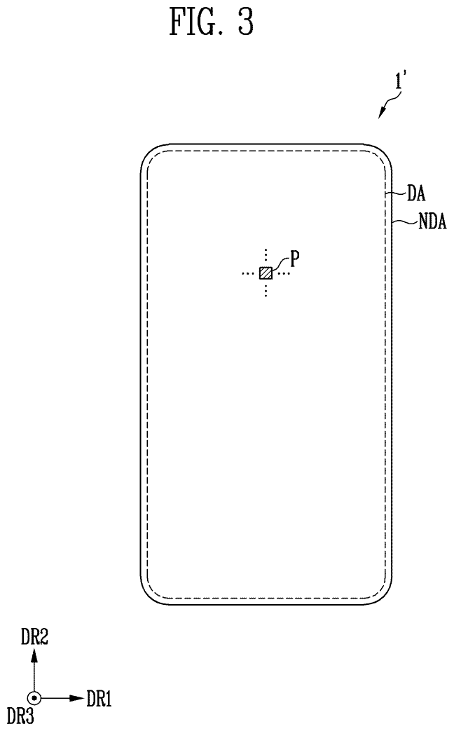

FIGS. 3-5 are plan views schematically illustrating an electronic device including a display device in accordance with embodiments of the present disclosure.

Referring to FIGS. 3-5, a display device 1, 1′, and 1″ may include a display area DA and a peripheral area NDA at the outside of the display area DA. A plurality of pixels P each including a display element may be in the display area DA, and the display device 1, 1′, and 1″ may provide an image, using light emitted from the plurality of pixels P in the display area DA. The peripheral area NDA is a kind of non-display area in which the display elements are not provided, and may be entirely surrounded by the peripheral area NDA.

In FIGS. 3-5, it is illustrated that the display area DA of the display device 1, 1′, and 1″ has a quadrangular shape having round corners. However, in another embodiment, the shape of the display area DA may be a circular shape, an elliptical shape, a polygonal shape such as a triangular shape or a pentagonal shape, or the like.

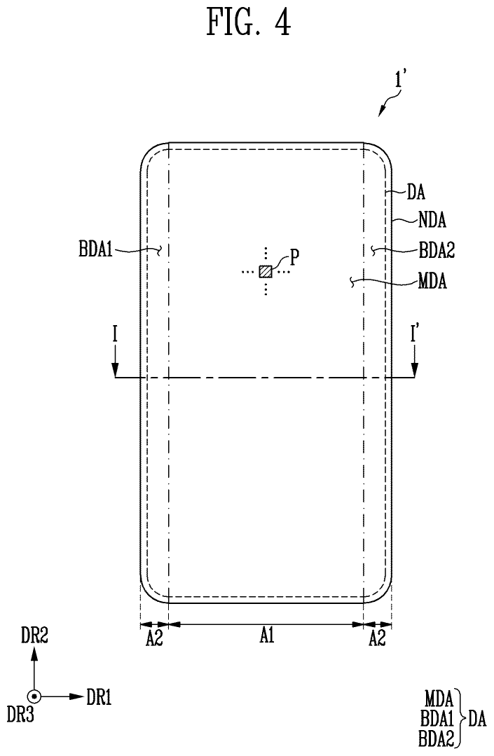

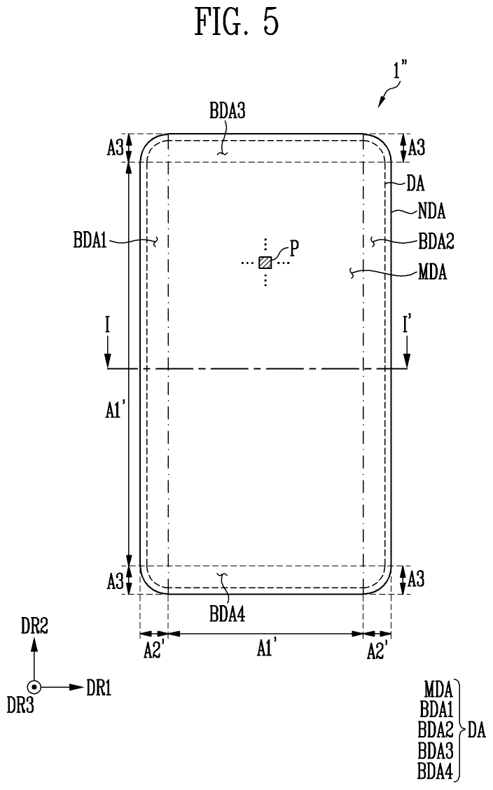

In FIGS. 4-5, the display device 1′ and 1″ in a form in which the display device 1′ and 1″ is flat before bending. However, the display device 1′ and 1″ in accordance with this embodiment may include a three-dimensional display surface or a curved display surface as shown in FIG. 2. For example, FIG. 2 described above may correspond to a cross-section taken along line I-I′ after display areas BDA1 to BDA4 of the display device 1′ and 1″ shown in FIG. 4 or 5 is bent.

When the display device 1′ and 1″ includes the three-dimensional display surface, the display device 1′ and 1″ may include a plurality of display areas indicating different directions (e.g., emitting light in different directions), and include, for example, a polygonal pillar-shaped display surface. In another embodiment, when the display device 1′ and 1″ includes the curved display surface, the display device 1′ and 1″ may be implemented in various suitable forms such as flexible, foldable, and/or rollable display devices.

The display device 1′ shown in FIG. 4 may include a first area A1 and second areas A2 respectively provided at both sides (e.g., two opposing sides) of the first area A1. The first area A1 may be, for example, a non-bending area, and the second area A2 may be a bending area bendable with or to a set or predetermined curvature. That the display device 1 has a bending area may mean that each of layers constituting the display device 1 has a bending area.

In an embodiment, the display area DA may include a main display area MDA corresponding to the above-described first area A1, and a first bending display area BDA1 and a second bending display area BDA2, which respectively correspond to the second areas A2.

The display device 1″ shown in FIG. 5 may include a first area A1′, and

second areas A2′ and third areas A3, which are respectively provided at four surface edges with respect to the first area A1′. The first area A1′ may be, for example, a non-bending area, and the second and third areas A2′ and A3 may be bending areas bendable with or to a set or predetermined curvature. The second areas A2 may be provided at left and right sides with the first area A1′ interposed therebetween, and be bent with respect to a bending axis in a major axis direction (e.g., a second direction DR2). The third areas A3 may be provided at upper and lower sides with the first area A1′ interposed therebetween, and be bent with respect to a bending axis in a minor axis direction (e.g., a first direction DR1). Accordingly, a display device having a four-surface bending structure can be manufactured.

Hereinafter, in this specification, the first direction DR1 will be designated as a “row” direction of the pixels P, and the second direction DR2 will be designated as a “column” direction of the pixels P. In embodiments, a display direction of the display device 1, 1′, and 1″ or a normal direction of a plane on which the display panel 10P is provided will be designated as a third direction DR3.

In an embodiment, the display area DA may include a main display area MDA corresponding to the above-described first area A1, a first bending display area

BDA1 and a second bending display area BDA2, which respectively correspond to second areas A2, and a third bending display area BDA3 and a fourth bending display area BDA4, which respectively correspond to third area A3. The first to fourth bending display areas BDA1 to BDA4 may be bent to face different directions.

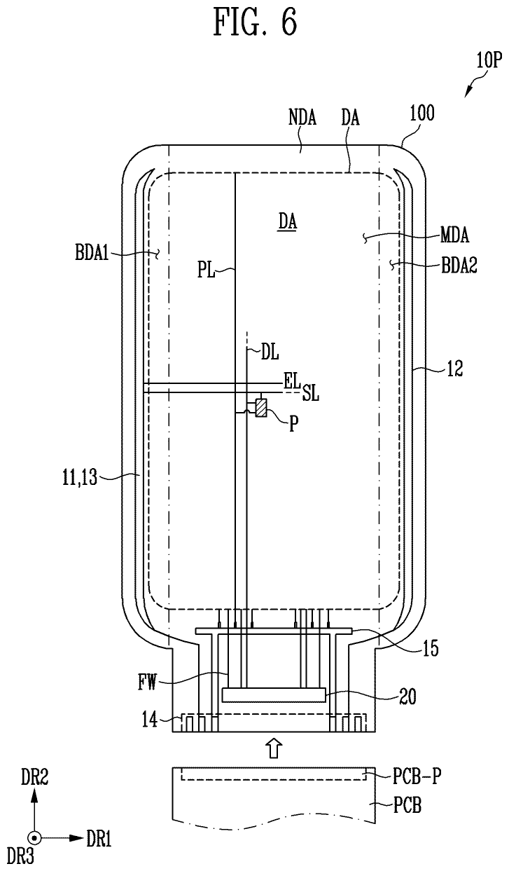

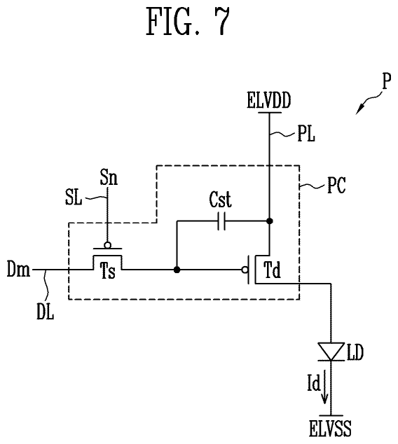

FIG. 6 is a plan view schematically illustrating a display panel in accordance with an embodiment of the present disclosure. FIG. 7 is an equivalent circuit diagram of a pixel in accordance with an embodiment of the present disclosure.

Referring to FIG. 6, the display panel 10P may include a substrate 100, and various suitable components constituting the display panel 10P may be on the substrate 100. A display area DA may include a main display area MDA as a non-bending area and first and second bending display areas BDA1 and BDA2 as bending areas adjacent to the non-bending area. The first and second bending display areas BDA1 and BDA2 may be respectively provided at both sides (e.g., two opposing sides) of the main display area MDA with the main display area MDA interposed therebetween. For example, the first and second bending display areas BDA1 and BDA2 may be provided adjacent to first and second scan driving circuits 11 and 12.

A plurality of pixels P may be in the display area DA. The plurality of pixels P may include at least one sub-pixel, and be implemented by a display element such as a light emitting diode. The plurality of pixels P may emit, for example, light of red, green, blue and/or white.

The plurality of pixels P in the display area DA may be electrically connected to outer circuits in a peripheral area NDA as a non-display area. The first scan driving circuit 11, the second scan driving circuit 12, an emission control driving circuit 13, a terminal 14, and a first power supply line 15 may be in the peripheral area NDA. In embodiments, a second power supply line may be provided outside the driving circuits (e.g., the first scan driving circuit 11, the second scan driving circuit 12, and the emission control driving circuit 13).

The first scan driving circuit 11 may provide a scan signal to each of the

plurality of pixels P through a scan line SL. The second scan driving circuit 12 may be provided parallel to the first scan driving circuit 11 with the display area DA interposed therebetween. Some of the plurality of pixels P in the display area DA may be electrically connected to the first scan driving circuit 11, and the others of the plurality of pixels P may be electrically connected to the second scan driving circuit 12. In another embodiment, the second scan driving circuit 12 may be omitted.

The emission control driving circuit 13 may be provided at a side of the first scan driving circuit 11, and provide an emission control signal to each of the plurality of pixels P through an emission control line EL. In FIG. 6, it is illustrated the emission control driving circuit 13 is provided at one side of the display area DA. However, like the first and second scan driving circuits 11 and 12, the emission control driving circuit 13 may be provided at both sides of the display area DA.

The terminal 14 may be in the peripheral area NDA of the substrate 100. The terminal 14 may be exposed without being covered by an insulating layer (e.g., an electrically insulating layer), to be electrically connected to a printed circuit board PCB. A terminal of the printed circuit board PCB may be electrically connected to the terminal 14 of the display panel 10P.

The printed circuit board PCB may transfer a signal or power of a controller to the display panel 10P. A control signal generated by the controller may be transferred to each of the driving circuits (e.g., the first scan driving circuit 11, the second scan driving circuit 12, and the emission control driving circuit 13) through the printed circuit board PCB. The controller may provide a driving voltage ELVDD to the first power supply line 15, and provide a common voltage ELVSS to the second power supply line. The driving voltage ELVDD may be provided to the pixel P through a driving voltage line PL connected to the first power supply line 15, and the common voltage ELVSS may be provided to a counter electrode of a pixel connected to the second power supply line. The first power supply line 15 may be provided to extend in one direction (e.g., the first direction DR1) at a lower side of the display area DA. The second power supply line may have a loop shape of which one side is opened, to be provided in the peripheral area NDA.

The controller may generate a data signal. The generated data signal may be transferred to an input line FW through a data pad portion 20, and be transferred to the pixel P through a data line DL connected to the input line FW.

Referring to FIG. 7, each pixel P may include a pixel circuit PC connected to a scan line SL and a data line DL and a light emitting diode LD connected to the pixel circuit PC.

The pixel circuit PC may include a driving transistor Td, a switching transistor Ts, and a storage capacitor Cst. The switching transistor Ts may be connected to the scan line SL and the data line DL, and transfer a data signal Dm input through the data line DL to the driving transistor Td according to a scan signal Sn input through the scan line SL.

The storage capacitor Cst may be connected to the switching transistor Ts and the driving voltage line PL, and store a voltage corresponding to a difference between a voltage transferred from the switching transistor Ts and the driving voltage ELVDD supplied to the driving voltage line PL.

The driving transistor Td may be connected to the driving voltage line PL and the storage capacitor Cst, and control a driving current Id flowing from the driving voltage line PL to the light emitting diode LD, corresponding to a voltage value store stored in the storage capacitor Cst. The light emitting diode LD may emit light having a set or predetermined luminance by the driving current Id.

Although a case where the pixel circuit PC includes two transistors and one storage capacitor is described in FIG. 7, the present disclosure is not limited thereto. In another embodiment, the pixel circuit PC may include, for example, seven transistors and one storage capacitor. In another embodiment, the pixel circuit PC may include two or more storage capacitors.

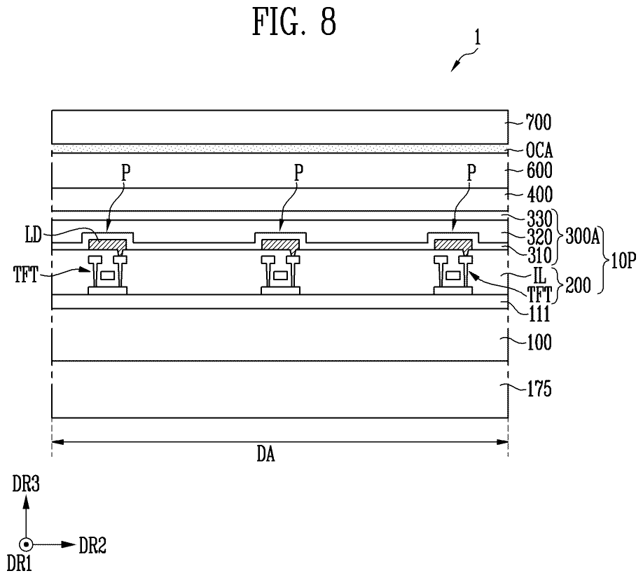

FIG. 8 is a cross-sectional view schematically illustrating a stacked structure of a display panel in accordance with an embodiment of the present disclosure.

Referring to FIG. 8, the display panel 10P may include a plurality of display elements for displaying an image.

Referring to FIG. 8, the display device 1 may include the display panel 10P, a substrate 100, a display layer 200 on the substrate 10, an encapsulation layer 300A on the display layer 200, an input sensing layer 400 on the display panel 10P, and an anti-reflection layer 600 on the input sensing layer 400.

The substrate 100 may include glass and/or polymer resin. For example, the polymer resin of the substrate 100 may include polyethersulfone, polyacrylate, polyether imide, polyethylene naphthalate, polyethylene terephthalate, polyphenylene sulfide, polyarylate, polyimide, polycarbonate, cellulose acetate propionate, and/or the like. The substrate 100 including the polymer resin may have a flexible, rollable and/or bendable characteristic. The substrate 100 may have a multi-layer structure including a layer including the above-described resin and an inorganic layer.

A buffer layer 111 may be provided on the substrate 100. The buffer layer 111 may reduce or block infiltration of a foreign matter, humidity and/or external gas from a bottom of the substrate 100, and provide a flat surface on the substrate 100. The buffer layer 111 may include an inorganic insulating material (e.g., an inorganic electrically insulating material) such as silicon oxide, silicon oxynitride, and/or silicon nitride, and may be provided as a single layer or a multi-layer, which includes the above-described material.

The display layer 200 may be on a front surface of the substrate 100, and a lower protective film 175 may be on a rear surface of the substrate 100. The lower protective film 175 may include an organic insulating material (e.g., an organic electrically insulating material) such as polyethylene terephthalate (PET) and/or polyimide (PI). The lower protective film 175 may be attached to a rear surface of the substrate 100. In embodiments, the lower protective film 175 may be formed directly on the rear surface of the substrate 100, and any adhesive layer may not be interposed between the lower protective film 175 and the substrate 100. In some embodiments, the lower protective film 175 may be omitted.

The display layer 200 may include a plurality of pixels. The display layer 200 may include a display element layer including a light emitting diode LD as a display element, a circuit layer including a transistor TFT electrically connected to the light emitting diode LD, and an insulating layer IL (e.g., an electrically insulating layer IL). The light emitting diode LD may be electrically connected to the transistor TFT to form a pixel P.

The display layer 200 may be sealed with an encapsulation member. In an embodiment, the encapsulation member may include the encapsulation layer 300A as shown in FIG. 8. The encapsulation layer 300A may include at least one inorganic encapsulation layer and at least one organic encapsulation layer. In an embodiment, the encapsulation layer 300A may include first and second inorganic encapsulation layers 310 and 330 and an organic encapsulation layer 320 interposed therebetween.

In another embodiment, the encapsulation member may include an encapsulation substrate. The encapsulation substrate may be provided to face the substrate 100 with the display layer 200 interposed therebetween. A gap may exist between the encapsulation substrate and the display layer 200. The encapsulation substrate may include glass. A sealant may be between the substrate 100 and the encapsulation substrate. The sealant may be in the peripheral area NDA described with reference to FIGS. 3-5. The sealant in the peripheral area NDA may prevent or reduce infiltration of moisture through a side surface while surrounding the display area DA.

The input sensing layer 400 may acquire coordinate information according to an external input, e.g., a touch event of an object such as a finger and/or a stylus pen. The input sensing layer 400 may include a touch electrode and a trace line connected to the touch electrode. The input sensing layer 400 may sense an external input, using a mutual cap method or a self-cap method.

The input sensing layer 400 may be formed on the encapsulation member. In embodiments, the input sensing layer 400 may be separately formed and then be bonded on the encapsulation member through an adhesive layer such as an optically clear adhesive. In an embodiment, the input sensing layer 400 may be formed directly on the encapsulation layer 300 or the encapsulation substrate. The adhesive layer may not be interposed between the input sensing layer 400 and the encapsulation layer 300A or the encapsulation substrate.

The anti-reflection layer 600 may decrease a reflectivity of light (external light) incident toward the display panel 10P from the outside.

In an embodiment, the anti-reflection layer 600 may include an optical plate having a retarder and/or a polarizer. The retarder may be of a film type (or kind) or a liquid crystal coating type (or kind), and include a λ/2 retarder and/or a λ/4 retarder. The polarizer may also be of a film type (or kind) or a liquid crystal coating type (or kind). The film type (or kind of) polarizer may include a stretched synthetic resin film, and the liquid crystal coating type polarizer may include liquid crystals provided in a set or predetermined arrangement.

In an embodiment, the anti-reflection layer 600 may include a filter plate including a black matrix and color filters. The filter plate may include color filters provided for each pixel, a black matrix, and an overcoat layer.

In an embodiment, the anti-reflection layer 600 may have a destructive interference structure. The destructive interference structure may include a first reflective layer and a second reflective layer, which are on different layers. First reflected light and the second reflected light, which are respectively reflected from the first reflective layer and the second reflective layer, may be destructively interfered with each other, and accordingly, the reflectivity of external light can be decreased.

A cover window 700 may be on the display panel 10P. The cover window 700 may be a flexible window. The cover window 700 may protect the display panel 10P while being easily bent according to an external force without (or substantially without) occurrence of cracks and/or the like. The cover window 700 may include glass, sapphire, and/or plastic. The cover window 700 may be, for example, an ultra-thin glass (UTG) and/or a colorless polyimide (CPI). In an embodiment, the cover window 700 may be one having a structure in which a flexible polymer layer is on one surface of a glass substrate, or be one configured to have only a polymer layer.

The cover window 700 may be on the anti-reflection layer 600 of the display panel 10P, and be bonded to the anti-reflection layer 600 by way of an adhesive layer OCA such as an optically clear adhesive.

In an embodiment, in FIG. 8, it is illustrated that the cover window 700 is bonded to the anti-reflection layer 600 by way of the adhesive layer OCA. However, in another embodiment, positions of the anti-reflection layer 600 and the input sensing layer 400 may be reversed to each other. The cover window 700 may be bonded to the input sensing layer 400 through the adhesive layer OCA.

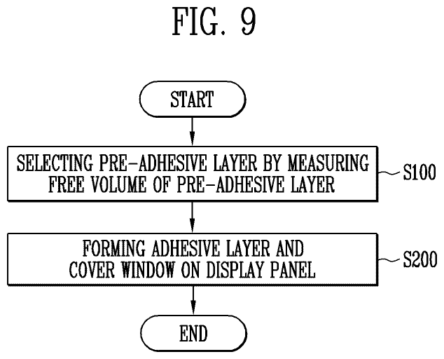

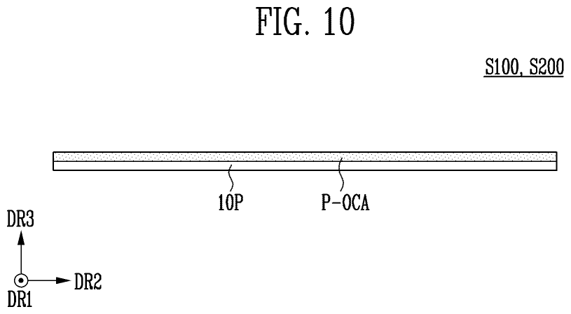

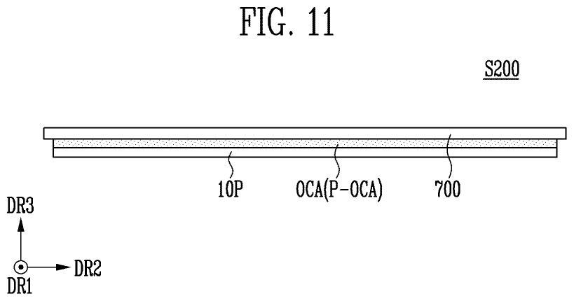

Hereinafter, a method of manufacturing the display device 1, 1′, and 1″ will be described with reference to FIGS. 9-11. FIG. 9 is a schematic flowchart illustrating a manufacturing method of a display device in accordance with an embodiment of the present disclosure. FIGS. 10-11 are schematic cross-sectional views illustrating process steps of a method in accordance with an embodiment of the present disclosure.

Referring to FIG. 9, the method may include step S100 of selecting a pre-adhesive layer by measuring a free volume of the pre-adhesive layer and step S200 of forming an adhesive layer and a cover window on a display panel.

Referring to FIG. 10, the step S100 of selecting the pre-adhesive layer by measuring the free volume of the pre-adhesive layer may be performed before the step S200 of forming the adhesive layer and the cover window on the display panel. For example, in the step S100 of selecting the pre-adhesive layer by measuring the free volume of the pre-adhesive layer, a pre-adhesive layer P-OCA which is to be used as an adhesive layer OCA may be selected, and the selected pre-adhesive layer P-OCA may be formed on a display panel 10P to form the adhesive layer OCA.

The step S100 of selecting the pre-adhesive layer by measuring the free volume of the pre-adhesive layer may include a step of measuring a free volume of a pre-adhesive layer and a step of selecting the pre-adhesive layer P-OCA satisfying a reference value.

The pre-adhesive layer may be a target adhesive layer of which free volume is measured. In the step of measuring the free volume of the pre-adhesive layer, the free volume of the pre-adhesive layer may be measured. The free volume of the pre-adhesive layer may be measured using a model suggested by Tao-Eldrup in a positive electron extinction method as described above.

The free volume of the pre-adhesive layer may be derived by measuring τ₃, deriving R, and then substituting R in 4/3×R³ in Expression 1. In Expression 1, R may mean an average radius of a pre-adhesive layer when the pre-adhesive layer is assumed to be a sphere.

In the step of selecting the pre-adhesive layer P-OCA satisfying the reference value, a pre-adhesive layer P-OCA having a free volume, which satisfies the reference value, may be selected. The reference value for selecting the pre-adhesive layer P-OCA may correspond to Expression 2.

$$Free Volume of Pre - adhesive \text{} Layer / Volume of Pre - adhesive Layer < 0.035 \qquad Expression 2$$

For example, in the step of selecting the pre-adhesive layer P-OCA, because the pre-adhesive layer P-OCA having a free volume of less than 3.5% of the volume (e.g., the total volume) of the pre-adhesive layer satisfies the reference value, the pre-adhesive layer P-OCA may be selected as a material for forming the adhesive layer OCA. In the step of selecting the pre-adhesive layer P-OCA, since a pre-adhesive layer having a free volume of 3.5% or more of the volume (e.g., the total volume) of the pre-adhesive layer does not satisfy the reference value, the pre-adhesive layer may not be selected as a material for the adhesive layer OCA. For example, a pre-adhesive layer satisfying Expression 2 may be selected as the material for the adhesive layer OCA, and the selected pre-adhesive layer may be applied on the display panel 10P, thereby forming the adhesive layer OCA.

Referring to FIGS. 10-11, the display panel 10P may be manufactured and provided before the step S200 of forming the adhesive layer and the cover window on the display panel. The display panel 10P may be previously provided before the adhesive layer OCA is formed.

The step S200 of forming the adhesive layer and the cover window on the display panel may include a step of laminating the selected pre-adhesive layer P-OCA on the display panel 10P, a step of forming a cover window 700 on the pre-adhesive layer P-OCA, and a step of performing an autoclave process.

In the step of laminating the pre-adhesive layer P-OCA on the display panel 10P, the pre-adhesive layer P-OCA satisfying the reference value may be laminated on the display panel 10P. The pre-adhesive layer P-OCA may be laminated using a roller, or be laminated by being input to a vacuum chamber. As the pre-adhesive layer P-OCA is laminated, the pre-adhesive layer P-OCA may be in contact with one surface of the display panel 10P.

In the step of forming the cover window 700 on the pre-adhesive layer P-OCA, the cover window 700 may be provided on the pre-adhesive layer P-OCA. The cover window 700 may be attached to the display panel 10P through the pre-adhesive layer P-OCA.

In the step of performing the autoclave process, an autoclave process may be performed on the pre-adhesive layer P-OCA, so that the adhesive layer OCA is formed. The autoclave process is a process of applying heat and pressure, and may remove bubbles caused by a lamination process.

As the autoclave process is performed at high temperature and high pressure, the autoclave process may remove bubbles caused by the lamination process. However, as external gas is dissolved under a high-temperature and high-pressure condition, infiltrated bubbles may occur. Accordingly, when a temperature and pressure condition of the autoclave process is lowered, the bubbles caused by the lamination process may not be removed. For example, removal of the bubbles caused by the lamination process and removal of the infiltrated bubbles are in a trade-off relationship. Therefore, it may be difficult to concurrently (or simultaneously) reduce the bubbles caused by the lamination process and remove the infiltrated bubbles.

In the method in accordance with embodiments of the present disclosure includes the step S100 of selecting the pre-adhesive layer by measuring the free volume of the pre-adhesive layer, so that the bubbles caused by the lamination process and the infiltrated bubbles can be concurrently (or simultaneously) reduced. The pre-adhesive layer P-OCA satisfying the reference value in the step S100 of selecting the pre-adhesive layer by measuring the free volume of the pre-adhesive layer can be used as the adhesive layer OCA, and occurrence of infiltrated bubbles can be reduced even when the autoclave process is performed at high temperature and high pressure.

When the pre-adhesive layer P-OCA have a free value of less than 3.5% of the volume (e.g., the total volume) of the pre-adhesive layer P-OCA, occurrence of infiltrated bubbles may be reduced even when the autoclave process is performed. For example, as the pre-adhesive layer P-OCA have a free value of less than 3.5% of the volume (e.g., the total volume) of the pre-adhesive layer P-OCA, a relatively small amount of external air may be introduced to the pre-adhesive layer P-OCA.

According to the method of embodiments of the present disclosure, occurrence of infiltrated bubbles may be relatively accurately predicted.

Previously, a Stress Relaxation (SR) measurement, a modulus measurement, and/or a creep test on the adhesive layer OCA was performed to predict occurrence of infiltrated bubbles. Because the accuracy of the SR measurement, the modulus measurement, and the creep test was relatively low, it was difficult to accurately predict an occurrence quantity of infiltrated bubbles even when the SR measurement, the modulus measurement, and/or the creep test had the same measurement value (e.g., the same SR measurement value, the same modulus measurement value, and/or the same creep test value). Accordingly, it was difficult to accurately predict a defect rate of the display device 1, 1′, and 1″.

As compared with this, according to the method of embodiments of the present disclosure, the free volume of the pre-adhesive layer P-OCA is measured, so that occurrence of infiltrated bubbles can be relatively accurately predicted.

Accordingly, the occurrence quantity of infiltrated bubbles can be predicted and reduced, so that the method having improved reliability against infiltrated bubbles can be provided.

In embodiments, the pre-adhesive layer P-OCA satisfying the reference value is selected, so that the adhesive layer OCA has a free volume of less than 3.5% of the volume (e.g., the total volume) of the adhesive layer OCA. Accordingly, the reliability against infiltrated bubbles can be improved, so that the method having a decreased defect rate can be provided.

In an embodiment, the method may further include a step of photo-curing the adhesive layer OCA. For example, a photo (e.g., ultra violet (UV))-curing process on the adhesive layer OCA may be further performed, and accordingly, the display device 1, 1′, and 1″ may be formed.

In accordance with embodiments of the present disclosure, there can be provided a display device and a method of manufacturing a display device, in which reliability against infiltrated bubbles can be improved.

A display device according to an embodiment is applicable to various types of electronic devices (or electronic apparatus). In an embodiment, an electronic device includes the above-described display device and may further include other modules or devices having additional functions in addition to the display device.

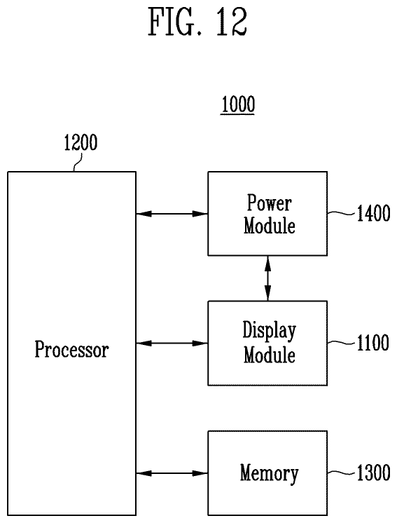

FIG. 12 is a block diagram of an electronic device according to an embodiment. Referring to FIG. 12, the electronic device 1000 may include a display module 1100, a processor 1200, a memory 1300, and a power module 1400.

The processor 1200 may include at least one of a central processing unit (CPU), an application processor (AP), a graphic processing unit (GPU), a communication processor (CP), an image signal processor (ISP), and a controller. The memory 1300 may store data and/or information used to operate the

processor 1200 or the display module 1100. When the processor 1200 executes an application stored in the memory 1300, image data signals and/or input control signals may be transferred to the display module 1100. The display module 1100 may process the provided signals and output image information on a display screen.

The power module 1400 may include a power supply module, such as a power adapter or a battery device, and a power conversion module. The power conversion module converts power supplied by the power supply module and generates power to operate the electronic device 1000.

At least one of the above-described components of the electronic device 1000 may be included in the display device according to embodiments as described above. In addition, in terms of functionality, some of the individual modules included in one module may be included in the display device and others may be provided separately from the display device. For example, the display module 1100 is included in the display device, whereas the processor 1200, the memory 1300, and the power module 1400 are not included in the display device and are instead provided separately in the electronic device 1000.

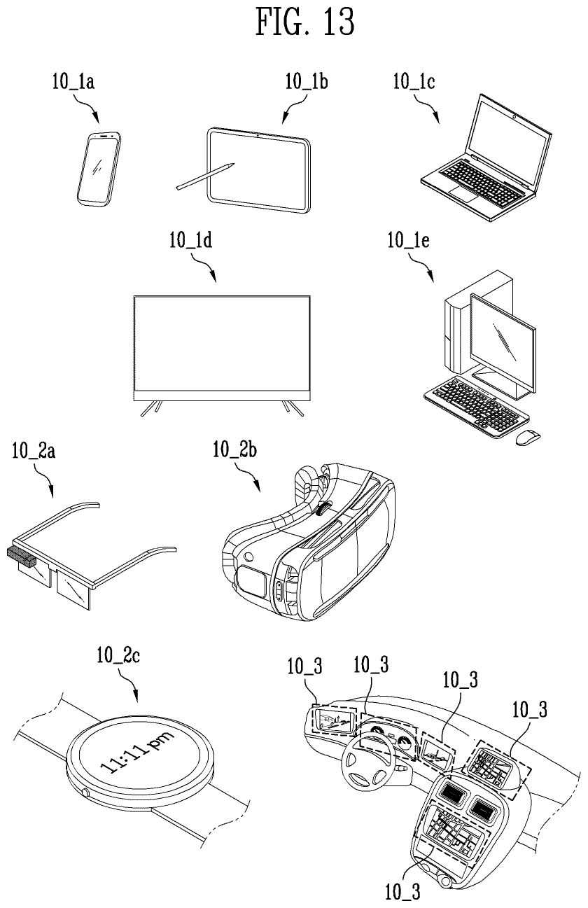

FIG. 13 shows schematic views of various embodiments of an electronic device.

Referring to FIG. 13, various types of electronic devices to which embodiments of a display device are applied may include an electronic device to display images such as a smartphone 10_1a, a tablet PC 10_1b, a laptop computer 10_1c, a television (TV) 10_1d, and a desktop monitor 10_1e, a wearable electronic device including a display module such as smart glasses 10_2a, a head-mounted display (HMD) 10_2b, and a smart watch 10_2c, and an automotive electronic device 10_3 including a display module such as a center information display (CID) disposed at the instrument cluster, the center fascia, and the dashboard of a vehicle, and a room mirror display.

Example embodiments have been disclosed herein, and although specific

terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various suitable changes in form and details may be made without departing from the spirit and scope of the present disclosure as set forth in the following claims, and equivalents thereof.

1 what is claimed is:

1. A method of manufacturing a display device, the method comprising:
selecting a pre-adhesive layer by measuring a free volume of the pre-adhesive layer; and
forming an adhesive layer and a cover window on a display panel,
wherein, in the selecting of the pre-adhesive layer, the pre-adhesive layer selected forms the adhesive layer.

2. The method of claim 1, wherein a free volume of the pre-adhesive layer selected is less than 0.035 times of a volume of the pre-adhesive layer.

3. The method of claim 2, wherein the selecting of the pre-adhesive layer comprises not selecting the pre-adhesive layer when the free volume of the pre-adhesive layer is 0.035 times or more of the volume of the pre-adhesive layer.

4. The method of claim 1, wherein, in the selecting of the pre-adhesive layer, the free volume is measured using a positive electron extinction method.

5. The method of claim 4, wherein the free volume is derived by substituting a value R calculated from Expression 1 in
$$\frac{4 π \text{?}}{\text{?}} :$$
$$\text{?} \text{indicates text missing or illegible when filed}$$
$$τ 3 = 0.5 \times {[ 1 - \frac{R}{R + Δ R} + \frac{1}{2 π} sin ( \frac{2 π R}{R + Δ R} ) ]}^{- 1} , \qquad Expression 1$$
wherein, in Expression 1, τ₃ is a lifetime of orthopositronium (o-PS), which is measured using the positive electron extinction method, R is an average radius of the free volume when the pre-adhesive layer is assumed to be a sphere, and AR is 0.1656 nm.

6. The method of claim 5, wherein the forming of the adhesive layer and the cover window on the display panel comprises:
laminating the pre-adhesive layer selected on the display panel;
forming the cover window on the pre-adhesive layer; and
performing an autoclave process.

7. The method of claim 6, wherein the laminating comprises laminating the pre-adhesive layer using a roller, or laminating the pre-adhesive layer by inputting the pre-adhesive layer to a vacuum chamber.

8. The method of claim 1, wherein, in the selecting of the pre-adhesive layer, the free volume is derived by substituting a value R calculated from Expression 1 in
$$\frac{4 π \text{?}}{\text{?}} ,$$
$$\text{?} \text{indicates text missing or illegible when filed}$$
and in the selecting of the pre-adhesive layer, the selected pre-adhesive layer satisfies Expression 2:
$$τ 3 = 0.5 \times {[ 1 - \frac{R}{R + Δ R} + \frac{1}{2 π} sin ( \frac{2 π R}{R + Δ R} ) ]}^{- 1} , \qquad Expression 1$$
wherein, in Expression 1, τ₃ is a lifetime of orthopositronium (o-PS), which is measured using a positive electron extinction method, R is an average radius of the free volume when the pre-adhesive layer is assumed to be a sphere, and AR is 0.1656 nm, and
$$Free Volume of Pre - adhesive \text{} Layer / Volume of Pre - adhesive Layer < 0.035 . \qquad Expression 2$$

9. The method of claim 8, wherein the adhesive layer is between the display panel and the cover window.

10. A display device comprising:
a display panel;
an adhesive layer on the display panel; and
a cover window on the adhesive layer,
wherein a free volume of the adhesive layer is less than 0.035 times of a volume of the adhesive layer.

11. The display device of claim 10, wherein the free volume is derived by substituting a value R calculated from Expression 1 in
$$\frac{4 π \text{?}}{\text{?}} :$$
$$\text{?} \text{indicates text missing or illegible when filed}$$
$$τ 3 = 0.5 \times {[ 1 - \frac{R}{R + Δ R} + \frac{1}{2 π} sin ( \frac{2 π R}{R + Δ R} ) ]}^{- 1} , \qquad Expression 1$$
wherein, in Expression 1, τ₃ is a lifetime of orthopositronium (o-PS), which is measured using a positive electron extinction method, R is an average radius of the free volume when the adhesive layer is assumed to be a sphere, and AR is 0.1656 nm.

12. The display device of claim 11, wherein a bottom surface of the adhesive layer is in contact with the display panel, and a top surface of the adhesive layer is in contact with the cover window.

13. An electronic apparatus comprising:
a display device; and
a housing accommodating the display device,
wherein the display device comprises:
a display panel;
an adhesive layer on the display panel; and
a cover window on the adhesive layer,
wherein a free volume of the adhesive layer is less than 0.035 times of a volume of the adhesive layer.
